(19) United States
(12) Patent Application Publication
(10) Pub. No.: US 2026/0177649 A1
(43) Pub. Date: Jun. 25, 2026

(54) METHOD AND APPARATUS FOR AUTOMATIC LOADING OF SHIM TRAYS

(71) Applicant: Siemens Healthineers AG, Forchheim (DE)

(72) Inventor: Johann SUKKAU, Herzogenaurach (DE)

(73) Assignee: Siemens Healthineers AG, Forchheim (DE)

(21) Appl. No.: 19/428,405

(22) Filed: Dec. 22, 2025

(30) Foreign Application Priority Data
Dec. 23, 2024 (DE) 10 2024 212 290.4

(51) Int. Cl. G01R 33/3873; B65G 43/00

(52) U.S. Cl. CPC G01R 33/3873; B65G 43/00

(57) ABSTRACT

The apparatus for automatic loading of a shim tray with shim elements includes a holding apparatus configured to position a shim tray, at least one cassette, a loading apparatus and a controller configured to control the loading apparatus. The cassette is configured to stock shim elements and/or separating elements. The loading apparatus is configured to deposit shim elements and/or separating elements from at least one cassette into a shim tray positioned by the holding apparatus.

### CROSS-REFERENCE TO RELATED APPLICATION(S)

The present application claims priority under 35 U.S.C. § 119 to German Patent Application No. 10 2024 212 290.4, filed Dec. 23, 2024, the entire contents of which are incorporated herein by reference.

### FIELD

One or more example embodiments relates to an apparatus and a method for automatic loading of shim trays with shim elements.

### RELATED ART

In magnetic resonance tomography (MRT) shim elements, also called shims or shim plates, are of crucial importance for homogenizing magnetic fields. Shimming refers to the process of adjusting a magnetic field, in the context of magnetic resonance tomography, in order to minimize image artifacts and improve the image quality. Various methods of shimming are known for this, including the basic shim or passive shimming. In passive shimming ferromagnetic materials are placed permanently in a magnetic field. Active shimming typically includes the use of electromagnetic coils which are regulated by a control current in order to adjust the magnetic field dynamically. The shim elements are arranged in what are known as shim trays, which are arranged on the MRT device in order optimally to align and/or balance the magnetic field.

A technical challenge when using shim elements is loading the shim trays. It is known that manual loading of the shim trays for passive shimming of the MR magnet is a time-consuming task requiring a high degree of precision. The magnet is typically measured using what is known as an array shim device, by which the homogeneity of the B0 field can be measured. After a subsequent calculation of the exact loading of the shim trays, the pockets of the shim trays are filled with shim elements by hand. This procedure demands a high level of attention from the person carrying it out and can moreover be time-consuming and tedious. As a result, there is an increased error rate when loading the shim trays. Due to the importance shown of the homogeneity of the magnetic field for medical imaging it is important to reduce errors as much as possible when loading the shim trays.

### SUMMARY

One or more example embodiments automates the process of loading the shim trays, increases the efficiency of loading the shim trays and minimizes errors when loading the shim trays.

### BRIEF DESCRIPTION OF THE DRAWINGS

Further advantages, features and details of the invention emerge from the exemplary embodiments described below and on the basis of the drawings. Parts corresponding to one another are provided with the same reference characters in all the figures.

In the drawings:

FIG. 1 shows a schematic representation of one form of embodiment of the proposed apparatus for automatic loading of a shim tray with shim elements in a first view,

FIG. 2 shows a schematic representation of a further form of embodiment of the proposed apparatus for automatic loading of a shim tray with shim elements in a second view,

FIG. 3 shows a schematic representation of a further form of embodiment of the proposed apparatus for automatic loading of a shim tray with shim elements,

FIG. 4 shows a schematic representation of a further form of embodiment of the proposed apparatus for automatic loading of a shim tray with shim elements,

FIG. 5 shows a schematic representation of a further form of embodiment of the proposed apparatus for automatic loading of a shim tray with shim elements,

FIG. 6 shows a three-dimensional schematic representation of a further form of embodiment of the proposed apparatus for automatic loading of a shim tray with shim elements, and

FIG. 7 shows a block diagram of a method for providing a loaded shim tray according to one or more embodiments.

### DETAILED DESCRIPTION

In accordance with one or more example embodiments an apparatus for automatic loading of a shim tray with shim elements is proposed. The apparatus comprises a holding apparatus for positioning a shim tray, at least one cassette, a loading apparatus and a control module (also referred to as a controller) for controlling the loading apparatus. The cassette is in this case designed to stock shim elements and/or separating elements. The loading apparatus is designed to deposit shim elements and/or separating elements from at least one cassette into a shim tray positioned by the holding apparatus.

A shim element is in particular a component designed for the adjustment and homogenization of magnetic fields, in particular in magnetic resonance tomography (MRT). For this purpose, the shim element can in particular have a particular shape or dimension. A shim element is typically designed as a sheet metal element with square dimensions. The shim properties of the shim element are typically determined via the thickness, i.e. the material thickness in the surface normal direction of the shim element. Shim elements typically consist of ferromagnetic materials. However, other magnetically influencing materials are also conceivable for shim elements. Thanks to the known and/or determinable properties of the shim element it is possible to carry out a precise magnetic correction of a magnetic field by positioning the shim element (and/or multiple shim elements). Shim elements can exist in different shapes, sizes and thicknesses, to meet different requirements and magnetic field anomalies.

The shim tray can in particular include multiple (shim) pockets. These (shim) pockets can be designed to accommodate one and/or multiple shim elements and/or separating elements. The (shim) pockets can be arranged, preferably spaced equally apart, contained by the shim tray. Shim trays can have different numbers of (shim) pockets, which can be arranged or spaced apart differently from one another.

The holding apparatus is in particular designed to accommodate a shim tray and/or to fix it in the apparatus at a predetermined position. In particular, the holding apparatus can be designed to hold the shim tray in a position using clamps, bolts, pins, rivets, latches and/or other locking elements. In particular, the holding apparatus can likewise be designed to fix multiple shim trays, for example side by side. In particular, the holding apparatus can be designed so that a shim tray can only be accommodated and/or fixed by the holding apparatus in a predetermined orientation. For example, the holding apparatus can have projections and/or contacting edges for the shim tray, which are designed as a counterpart to the geometry of the shim tray.

The cassette can in particular be a container for storing and transporting shim elements. The cassette can accordingly enable a plurality of shim elements to be handled and/or stored. The cassette can preferably be designed as a cuboid container. In particular, the cassette can include a cavity bounded by walls for accommodating shim elements. The cassette is in particular designed to accommodate and/or fix a plurality of shim elements horizontally one above the other in the cassette in the form of a stack. For this, the cassette can in particular have guide elements in the form of guide rails, for example. Moreover, the cassette can in particular include a lifting apparatus for the vertical movement of the stack of shim elements, in particular for raising it. For example, the cassette can include one or more lifting cylinders, which are designed and/or arranged to raise and/or lower a baseplate on which a stack of shim elements can be placed. The lifting apparatus can likewise be included in the apparatus. For example, the apparatus can include a lifting cylinder which from outside the cassette can act on a baseplate for the vertical movement thereof.

The loading apparatus can in particular be controlled via the control module using control commands. The loading apparatus can in particular be designed in each case to transport one and/or multiple shim elements from a position, preferably a stocking cassette, to another position, preferably the shim tray. The loading apparatus can in particular be designed to isolate a shim element from a plurality of shim elements. The loading apparatus can in particular be designed to fix a shim element, in particular mechanically, magnetically and/or pneumatically. The loading apparatus can in particular be designed to move a shim element in a first, second and/or third direction and/or to adjust the orientation of the shim element, in particular by rotating the shim element about one and/or multiple axes of rotation.

The control module can in particular include a computing and/or storage unit. The storage unit can in particular be designed to store loading information. For example, the storage unit can store a loading plan for a shim tray for a predetermined magnetic resonance apparatus. In particular, other information, for example magnetic measurement data, can be saved using the storage unit. In particular, a loading plan for a shim tray can be determined using a computing unit. In particular, control commands for the loading unit of the apparatus can moreover be determined using the computing unit. In particular, the control module can moreover include a user interface. Via the user interface a user can be enabled to start, interrupt, monitor and/or adjust the loading of the shim tray.

The (isolated) shim elements are preferably stacked separately in the shim tray via separating elements (also referred to as intermediate elements). The separating elements are preferably made of plastic. Via the separating elements it is preferably possible to prevent the shim elements from adhering directly to one another and/or coming into direct contact with one another when they are arranged one above the other in the shim tray.

The proposed apparatus for automatic loading of shim trays with shim elements advantageously enables the automation of the loading process for shim trays. As a result, it is possible to significantly increase efficiency and reduce the time-consuming, manual filling of the shim trays. This can lead to a significant reduction in working time and less work for the operating personnel, who would otherwise have to achieve a high degree of precision and pay close attention. Furthermore, the error rate when loading the shim trays can be significantly minimized. The automatically loaded shim trays can result in particular in the improved homogeneity of a magnetic field and thus to an optimized image quality in magnetic resonance tomography. The apparatus can enable the shim elements and/or separating elements to be deposited precisely and in a controlled manner, going beyond what can be achieved manually. In general, the apparatus can also increase the reliability and repeatability of shimming.

In accordance with one or more example embodiments the loading apparatus includes a movement unit and a fixing unit. The movement unit is designed to move and/or position the fixing unit. The fixing unit is designed to fix a shim element and/or separating element.

In accordance with one or more example embodiments the loading apparatus, in particular the movement apparatus (also referred to as a movement unit), includes at least one robot arm. The fixing unit can preferably be moved via the movement apparatus, in particular the robot arm, in a set movement volume. A robot arm typically consists of the following components: an articulation, a motor, a control unit, a sensor, an end effector and an arm element. The sensor can in particular be designed to detect the position and movement of the robot arm and/or of a part of the robot arm, as well as of the surrounding area. The sensor can for example include a rotary encoder, force sensor and/or camera. The motor can in particular be designed to drive the articulations and/or to move the arm. The motor can comprise an electric, hydraulic and/or pneumatic drive. The end effector can in particular be a tool and/or an apparatus at the end of an arm. In particular, the end effector can include the fixing unit. The control unit can in particular include microprocessors and a program product for controlling the robot arm, in particular for controlling the articulations and/or motors. The articulation can in particular be designed as a rotary articulation and/or pivotable articulation. The control unit of the robot arm can be included in the control module.

In particular, via the movement apparatus the fixing unit can be moved and/or displaced to a position (inside) the apparatus. In particular, via the movement apparatus the fixing unit can be positioned, so that the fixing unit can be placed at/on the shim element to be loaded. In other words, the movement apparatus enables the fixing unit to approach a shim element. The movement apparatus can preferably be connected to the control module, for example via a cable connection. The control module can preferably be designed to send control signals to the movement unit and/or fixing unit.

The fixing unit in particular includes an element for fixing a shim element, for example a suction element and/or a magnetic element. Moreover, the fixing unit can include a further movement apparatus, in particular to move the element for fixing a shim element. For example, the fixing unit can include a rotary apparatus. The fixing unit is in particular designed to fix a shim element via the element, in particular via a suction element and/or a magnetic element, and via a preferably vertical movement to separate it from the stack of shim elements, in particular located in an isolated manner in a cassette. The fixing unit is in particular designed to remove the shim element from the cassette. The fixing unit is in particular designed to deposit the fixed shim element at a predetermined position and/or location in the shim tray. In other words, via the fixing unit a shim element can be separated from the plurality of shim elements in the cassette and removed from the cassette and positioned into the shim tray. Besides the preferred loading of the shim tray from the cassette by a shim element, further intermediate movements, such as the rotation of the shim element and/or the examination of the shim element at an examination station designed for this purpose are conceivable. For example, it is conceivable for a shim element to be removed or inserted at a predetermined angle out of the cassette and/or into the shim tray. Moreover, it is conceivable for example for a shim element to be raised and/or tilted by the fixing unit and then to be transported out of the cassette with a movement.

The loading apparatus, which includes a movement unit and a fixing unit, can advantageously be enabled to load the shim tray with shim elements efficiently and precisely. In particular, the fixing unit can ensure that an isolated shim element can only be deposited at a predetermined location during the loading process. Thanks to the movement unit the fixing unit is advantageously enabled to move efficiently and precisely within the apparatus.

In accordance with one or more example embodiments the movement unit includes up to three linear movement elements and/or up to three rotary elements. The linear movement elements are designed for the linear movement of the fixing unit in a first, second and third direction. The rotary elements are designed for the orientation and/or rotation of the fixing unit about a first, second and third axis of rotation.

A linear movement element is typically designed to convert a circular movement generated by a motor into a linear movement along an axis. A linear movement element can also be referred to as a linear axis. Thanks to this linear movement along an axis the linear movement element can in particular be designed to move and/or displace an object, in particular the fixing unit. In other words, an object, in particular actively driven, can be pulled, pressed, raised, lowered or tilted along a track via a linear movement element. In particular, linear movement elements can be arranged nested, linked and/or connected. This can enable an object to move and/or be displaced in more than one direction. This linking and/or combination of multiple linear movement elements can also be referred to as a linear system.

A linear movement element can typically include the following components: a roller, a profile, a sensor unit, for example a magnetically encoded position measuring system, a slide, a control unit, a sliding element and/or magnets. One (or more) rollers can here preferably enable a movement of a slide in a profile. For example, a sliding element can however also be provided and/or included in the slide. The control is preferably effected via a sensor unit in conjunction with a control unit. In this case, the control unit preferably receives measured signals from the sensor. The control unit is in particular designed to analyze the measured signals from the sensor and/or to send a corresponding movement signal to the linear movement element, in particular the moving slide, and/or to the drive unit/motor. The control unit of the linear movement element can be included in the control module.

A rotary element is typically designed to rotate an object in reference to an axis of rotation. In other words, a rotary element can thus change the spatial orientation of an object, in particular the fixing unit. A rotary element can also be referred to as an axis of rotation. Thanks to this rotational movement along an axis, the rotary element can, in particular in combination with one and/or multiple linear movement elements, be designed to move, spatially align, rotate and/or displace an object, in particular the fixing unit. In other words, an object, in particular actively driven, can be rotated and/or tilted about an axis and/or a point via a rotary element. In particular, rotary elements can be arranged nested, linked and/or connected. This can enable an object to be aligned in more than one direction. This linking and/or combination of multiple rotary elements can also be referred to as an alignment system.

For example, the movement apparatus can include a linear movement element which is divided into two sections. These two linear movement elements can enable the (simultaneous) movement of two fixing apparatuses, preferably in a second direction (Y-direction). In a first (X-direction) and a third direction (Z-direction), the movement apparatus can in each case comprise a combination of a linear movement element and a rotary element. A combination of up to three linear movement elements and up to three rotary elements can enable a compactly designed movement apparatus. A movement apparatus equipped with linear movement elements and/or rotary elements can advantageously enable the particularly simple, robust and reliable control of the movement facility and/or movement of the fixing unit.

In accordance with one or more example embodiments the fixing unit includes a suction element. The suction element is designed to fix a shim element and/or separating element by generating a negative pressure.

The suction element can preferably be designed in the form of a suction cup and/or a vacuum gripper. The suction element is preferably designed to generate a negative pressure, partial vacuum and/or vacuum on a surface of the shim element. In particular, the generation of this negative pressure, partial vacuum and/or vacuum can be achieved by connecting the suction element to a negative pressure and/or vacuum generator. The connection between the suction element and the negative pressure and/or vacuum generator can preferably be effected via a hose connection. The generation of a negative pressure for fixing the shim element can also in particular be effected mechanically, similarly to a typical suction cup. By applying a pressure to the suction element, for example by the selection apparatus, the generation of a negative pressure can be effected. In other words, the suction element is designed to suck a shim element in. In addition, for example by reversing the negative pressure generator to apply a positive pressure, the suction element can be designed to release the fixing of a shim element again at a controllable time after fixing.

A fixing apparatus formed by a suction element can advantageously enable safe and stable fixing of the shim element. The precision and accuracy of the loading process can be increased as a result. Moreover, misalignments can be prevented and it can be ensured that the shim elements are placed exactly in the intended positions in the shim tray. Moreover, fixing using negative pressure can allow smooth and fast handling of the shim elements.

In accordance with one or more example embodiments the fixing unit includes a magnetic element. The magnetic element is designed to fix a shim element and/or separating element magnetically.

The magnetic element can preferably be designed in the form of a permanent magnet and/or an electromagnetic gripper. The magnetic element is preferably designed, supported on a surface of the shim element, to generate an attractive force between the shim element and the magnetic element by applying a magnetic field. In particular, the magnetic field generated by the magnetic element can be controlled and/or switched on and off in this case. The generation of the magnetic field by the magnetic element can in particular be effected by an electromagnet. In other words, a shim element can be fixed and/or gripped by the magnetic element by switching on the magnetic field. In addition, for example by switching off the magnetic element, the magnetic element can be designed to release the fixing of a shim element again at a controllable time after fixing.

A fixing apparatus formed by a magnetic element can advantageously enable safe and stable fixing of the shim elements. The precision and accuracy of the loading process can be increased as a result. Moreover, misalignments can be prevented and it can be ensured that the shim elements are placed exactly in the intended positions in the shim tray. Moreover, the magnetic fixing can enable smooth and fast handling of the shim elements.

In accordance with one or more example embodiments the apparatus includes at least one sensor for monitoring the automatic loading of the shim tray.

The apparatus can include one or more sensors. The sensor can be designed in particular to monitor the automatic loading of the shim tray and can be arranged accordingly in the apparatus. For example, the sensor can alternatively and/or additionally include a level sensor, a camera, a movement sensor, a weight sensor and/or another monitoring sensor. In particular, thanks to the sensor the loading apparatus, in particular the movement unit and the fixing unit, can detect and/or determine a fill level of the cassettes and/or of the shim tray, an isolation, nature and/or orientation of the shim elements, and/or a position of a user of the apparatus. The sensor can preferably transmit measurement signals, results and/or information to the control module of the apparatus. The control module can use these signals and/or information to modify, stop, start the loading of the shim tray 2 and/or to issue (warning) information to the user of the apparatus via a user interface.

The sensor advantageously enables automatic monitoring of the loading of the shim tray. As a result, the necessary monitoring by an operator/user can advantageously be reduced. Thus for example the number of users/operators of the apparatus can be reduced and/or a user can be enabled to operate multiple systems at the same time. In particular, the sensor enables the detection and documentation of incorrect depositing procedures or shim trays, as a result of which the quality and/or correctness of the automatically loaded shim trays can be controlled.

In accordance with one or more example embodiments the apparatus is designed as a mobile apparatus.

In particular, the apparatus designed as a mobile apparatus is spatially displaceable and/or portable. In other words, the apparatus designed as a mobile apparatus can be moved in a facility, for example a workshop and/or production facility, from one position, in particular a magnetic resonance apparatus, to another position, in particular a further magnetic resonance apparatus. In particular, the apparatus can include a drive apparatus. The drive apparatus can in particular enable the apparatus to be moved and/or displaced. For example, the drive apparatus 11 can include multiple wheels, axles and/or a drive motor. However, the drive apparatus can for example include a crawler drive, chain drive and/or other drive.

In particular, via a drive unit, the apparatus is advantageously designed as a mobile apparatus. For example, an apparatus designed to be mobile enables one and/or multiple shim trays to be loaded in the vicinity of a magnet. In particular in the production of magnetic resonance systems, this can reduce necessary transport distances and time. This can be advantageous for the efficient production of magnetic resonance systems.

In accordance with one or more example embodiments the apparatus includes a locking apparatus. The locking apparatus is designed to lock at least one cassette.

The locking apparatus can preferably be designed to accommodate and/or fix at least one cassette. For each cassette to be accommodated the locking apparatus can have a respective position to lock the cassette. The locking apparatus can include a plate, a table and/or a metal sheet. The locking apparatus can have recesses, edges, strips and/or predeterminedly arranged (in a pattern) fastening elements, such as bolts, pins and the like.

Thanks to the locking apparatus a user can advantageously be enabled to position the cassettes precisely. In the case of a plurality of different shim elements, it is possible to specify to a user via the locking apparatus in which position which cassette should be positioned. As a result, the incorrect and/or erroneous positioning (and possibly incorrect loading as a result) can be reduced.

In accordance with one or more example embodiments the locking apparatus is designed to accommodate at least one cassette and has a locking element for each cassette to be accommodated. Each locking element is in this case designed to lock a cassette fitted exactly in pairs to the locking element.

Each locking element can be designed such that it fits to a cassette exactly in pairs. The locking apparatus can for example alternatively or additionally include locking elements in the form of an encoding, a sensor, an electronic contact, a marking or the like. Via the locking element, the cassette can be locked and/or fixed in the locking apparatus. The locking of the cassette in the locking apparatus can here be effected mechanically, pneumatically, magnetically and/or electronically.

Advantageously, a locking element designed to fit to a respective cassette exactly can enable the cassettes to be positioned and fixed precisely. In the case of differently designed cassettes, mistakes and/or incorrect positioning of the cassettes can be reduced by respectively designed locking elements.

In accordance with one or more example embodiments the apparatus includes at least one isolation apparatus for the at least one cassette. The isolation apparatus is designed to output an isolated shim element and/or separating element from the cassette.

In particular, the isolation apparatus can include an apparatus to isolate shim elements. The apparatus can preferably include a cassette to store a plurality of shim elements. The shim elements can in particular be arranged horizontally one above the other in the cassette in the form of a stack. The apparatus can include a separation apparatus for isolating a shim element. The separation apparatus is designed to remove a shim element from the cassette via a horizontal sideways movement.

The cassette can in particular be a container for storing and transporting shim elements. The cassette can accordingly enable the handling and/or storage of a plurality of shim elements. The cassette can preferably be designed as a cuboid container. In particular, the cassette can include a cavity bounded by walls for accommodating shim elements. The cassette is in particular designed to accommodate and/or fix a plurality of shim elements horizontally one above the other in the cassette in the form of a stack. For this purpose the cassette can in particular have guide elements in the form of guide rails, for example. Moreover, the cassette can in particular include a lifting apparatus for vertical movement of the stack of shim elements, in particular for raising it. For example, the cassette can include one or more lifting cylinders which are designed and/or arranged to raise and/or lower a baseplate on which a stack of shim elements can be placed. The lifting apparatus can likewise be included in the apparatus. For example, the apparatus can include a lifting cylinder which from outside the cassette can act on a baseplate for the vertical movement thereof.

The separation apparatus in particular includes an element for fixing a shim element, for example a suction element and/or a magnetic element. Moreover, the separation apparatus can include a movement apparatus, in particular for moving the element to fix a shim element. The separation apparatus is in particular designed to fix a shim element via the element, in particular via a suction element and/or a magnetic element, and to separate it from the stack of shim elements with a horizontal sideways movement and to remove the shim element from the cassette. In other words, via the separation apparatus a shim element can be separated from the plurality of shim elements in the cassette and pushed and/or pulled sideways out of the cassette. Besides the preferred isolation of a shim element by a horizontal sideways movement, further separation and/or isolation movements are also conceivable. For example, it is conceivable for a shim element to be removed from the cassette at a predetermined angle. It is moreover conceivable for example to raise and/or tilt a shim element and then transport it out of the cassette with a movement.

The apparatus for isolating shim elements can advantageously enable the reliable, precise and automated separation of shim elements. Even if shim elements adhere to one another due to oil-soaked storage or material-related properties, the proposed apparatus can enable efficient handling. Moreover, automated isolation for example enables damage to the shim elements and/or incorrect separation to be minimized compared to manual isolation.

In accordance with one or more example embodiments the apparatus includes an inspection apparatus. The inspection apparatus is designed to detect the nature and/or condition of a shim element and/or separating element prior to loading the shim tray and to inspect this on the basis of specification information.

In particular, the specification information can include a predetermined nature and/or predetermined condition of a shim element. For example, differently designed shim elements can differ in dimensions, shape and/or material properties. On the basis of the nature and/or condition of the shim elements, these can be loaded into a shim tray, so that an inspection may be necessary before they are deposited. The inspection apparatus can include sensors for detecting the nature and/or condition, such as a camera, a scale, a resistance meter, a contact meter, a micrometer clock, a shape template and/or other detection means. In particular, the detection of the nature and/or condition of a shim element and/or of a separating element can include a determination of the thickness/height, dimension(s) and/or metal content of a shim element and/or a separating element. Before the shim element and/or separating element are deposited, a comparison of the determined nature and/or condition and of the specification information can be made. If a deviation is established the shim element can for example be replaced by another one or the nature and/or condition can for example be corrected by an alignment device. The inspection apparatus can be integrated into a component of the apparatus. In particular, however, the inspection apparatus can be arranged in an adjacent position in the apparatus with respect to the cassettes.

Via the inspection apparatus it can advantageously be ensured that the shim element determined by specification information can be determined and can be loaded in the shim tray. Faulty shim elements can advantageously be identified in this way. Overall the efficiency of the apparatus can therefore be advantageously increased.

In accordance with one or more example embodiments the apparatus includes an alignment apparatus. The alignment apparatus is designed to align a shim element and/or separating element on the basis of orientation information prior to loading the shim tray.

In particular, the orientation information can include a predetermined spatial orientation of a shim element. For example, the shim elements can be present in the cassettes in a different spatial orientation, so that an orientation correction may be necessary prior to depositing. The alignment apparatus can include sensors for detecting the spatial orientation, such as for example a camera, an orientation template and/or other detection means. The alignment apparatus can be included in a component of the apparatus. In particular, the alignment apparatus can however be arranged at an adjacent position in the apparatus in respect of the cassettes. For example, the alignment apparatus can include a turntable. In particular, the alignment apparatus can include an apparatus for rotating the plates in one or more axes and/or directions. The shim elements can preferably be deposited automatically into the alignment apparatus via the loading apparatus. The orientation can in particular be detected visually and can be corrected by an appropriately determined rotation.

Via the alignment apparatus it can advantageously be ensured that the spatial orientation of a shim element corresponds to an orientation determined by orientation information. Incorrectly oriented shim elements can advantageously be identified and corrected and deposited into the shim tray. Overall therefore the efficiency of the apparatus can advantageously be increased.

In accordance with one or more example embodiments the control module for controlling the loading apparatus is designed on the basis of shim information of a magnetic resonance apparatus.

The shim information can in particular include information about the magnet of a magnetic resonance apparatus and/or the formation of a magnetic field to be shimmed of a magnetic resonance apparatus. The shim information can for example be determined by a measurement of the magnetic field. The shim information can represent the input information for the control module. Via the shim information, the control module can determine loading information, in particular a loading plan, for one and/or multiple shim trays. In particular, via the loading plan and/or the loading information the loading of a shim tray can be effected by the control module. In other words, the control module can be designed to translate the shim information of a magnetic resonance apparatus into control signals to control the inventive apparatus. For example, the shim information can include information about the B0/homogeneity state of a magnetic field. For example, this information can be translated by the control module into further information and/or instructions, which in particular contain the identity (ID) of the shim tray, the numbers of the shim pockets and the list of shim plates per pocket. This (shim) information can then for example be used by the control module for loading.

An apparatus designed in this way advantageously enables the input of shim information as preferably the only input information. Thus an efficient apparatus for loading a shim tray for a magnetic resonance apparatus can advantageously be provided.

Moreover, in accordance with one or more example embodiments a method for providing a loaded shim tray is proposed. The method includes multiple steps. One step includes the detection of shim information. Another step includes the loading of a shim tray with shim elements via an apparatus in accordance with one of the above-described embodiments of the apparatus on the basis of the shim information. Another step includes the provision of the loaded shim tray.

The detection of shim information in particular includes the receipt and/or storage of the shim information by the control module of an apparatus in accordance with one of the above-described embodiments (referred to below for short as apparatus).

The loading of a shim tray with shim elements via an apparatus in accordance with one of the preceding apparatus claims on the basis of the shim information can in particular include the determination of control commands for the apparatus on the basis of the shim information. On the basis of the control commands the automatic loading of a shim tray can be effected via the apparatus. For this purpose for example a shim element and/or separating element to be loaded can be determined in a cassette, fixed, transported to the shim tray via the loading apparatus and deposited. In addition, further steps can be included, such as the alignment of the orientation of a shim element and/or separating element, the inspection of the nature of a shim element and/or separating element and/or the inspection of the loading of the shim tray by a sensor.

Advantageously, thanks to the proposed method an efficient, automatic loading of a shim tray for shimming a magnetic field is enabled. As a result, the time and resources required to load a shim tray can be reduced.

In addition, the advantages of the proposed method substantially correspond to the advantages of the proposed apparatus. Features, advantages or alternative forms of embodiment/aspects of the apparatus can likewise be transferred to the other claimed subject matters and vice versa.

In accordance with one or more example embodiments the method includes the isolation of the shim elements from at least one cassette. The loading of the shim tray includes the deposit of an isolated shim element on the basis of the shim information.

Isolation can include the removal of at least one isolated shim element from the cassette. Isolation can in turn include multiple steps. One step can include the removal of a shim element from the cassette via a, preferably horizontal, sideways movement. Another step can be the deposit of an isolated shim element into a deposit cassette, a deposit site and/or another apparatus for storing isolated shim elements. Another step can moreover include the separation and/or release of a shim element out of/from a plurality of shim elements, in particular arranged as a stack. For this purpose, a shim element can optionally be fixed via a separation apparatus. Moreover, the stack of shim elements can optionally be fixed (or in other words held). Another step can include the approach and/or pressing of one or more shim elements, in particular of a stack, to a guide element, in particular via a lifting apparatus.

The isolation can enable the precise and automatic separation of the shim elements. Even if shim elements adhere to one another due to oil-soaked storage or material-related properties, efficient handling can be enabled in this way.

FIG. 1 shows a schematic representation of the proposed apparatus 10 for automatic loading of a shim tray 2 with shim elements in a first form of embodiment. The schematic representation is illustrated in a first view, in particular a plan view. The apparatus 10 of this form of embodiment includes a shim tray 2, a holding apparatus 1 for a shim tray 2, a loading apparatus 4, a control module 5 and a plurality of cassettes 6a, 6b, 6c with shim elements and/or separating elements. The plurality of cassettes 6a, 6b, 6c can likewise be illustrated below by the reference character 6. If reference is made to one of the cassettes 6, this is illustrated by way of example by the cassette 6a.

Via the shim elements, minimization of image artifacts and an improvement in image quality in particular in magnetic resonance tomography systems can be achieved. In particular, the defined placement of the shim elements inside/on a magnet of a magnetic resonance tomography system can ensure a uniform and stable magnetic field. Shim elements are typically arranged in shim trays in a predetermined position on the magnet for this purpose. For storage and/or stocking, the shim elements can be placed and/or transported in a cassette 6. At least one cassette 6 can be included by the apparatus 10. In particular, the apparatus 10 and/or the cassette 6 can be designed such that it is possible to fit, remove and/or replace a cassette 6 in the apparatus 10. Moreover, in particular multiple cassettes 6, in particular with different shim elements, can also be included by the apparatus. The cassette 6 can be designed in particular in the form of a cuboid and/or a cylinder. In particular, the cassette can have 6 multiple wall elements, which in particular bound the cassette. The cassette 6 can in particular have a side and/or place which allows a shim element to be removed by an isolation apparatus (not shown).

The loading apparatus 4 can in particular be arranged in a vertical direction (characterized by x in FIG. 1) above the cassette 6 and/or the shim tray 2. The loading apparatus 4 can preferably be arranged opposite a side of the cassette 6 and/or of the shim tray 2 that is designed to be open and/or accessible. The loading apparatus 4 can in particular be designed to be displaceable and/or movable. As a result, the loading apparatus 4 can approach the cassettes 6 and/or the shim tray 2, and in particular a shim element. The shim element can be fixed via the loading apparatus 4, for example via an included vacuum gripper. The shim element can be guided out of a cassette 6a via the loading apparatus 4, for example by a horizontal sideways movement. A shim element can preferably be isolated by a movement of the loading apparatus 4. However, it is also conceivable for example for the cassettes 6 to be displaceable in respect of the loading apparatus 4, in order to guide the shim element out of the cassette 6a.

The isolated shim element can in particular be transported via the loading apparatus 4 from the cassette 6a to a position in the shim tray 2. Via the loading apparatus 4 the shim element can preferably be positioned in a predetermined position inside the shim tray 2, in particular by depositing the shim element.

The loading apparatus 4 can in this case in particular be controlled by the control module 5. For this purpose, the control module 5 can in particular send control signals to the loading apparatus 4. The control module 5 can moreover in particular include a computing and/or storage unit. The control module 5 can in particular be designed to store loading information and/or shim information. For example, the control module 5 can store a loading plan for a shim tray 2 for a predetermined magnetic resonance apparatus. In particular, other information, such as for example magnetic measurement data, can also be saved via the control module 5. In particular, the control module 5 can be used to determine a loading plan for a shim tray 2. In particular, the control module 5 can moreover be used to determine control commands for the loading unit 4 of the apparatus.

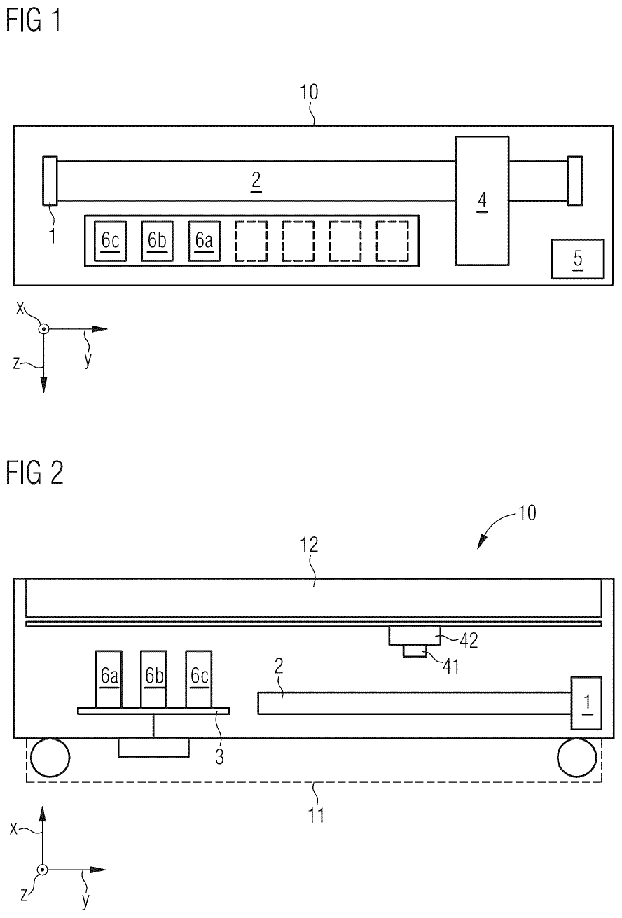

FIG. 2 shows a schematic representation of the proposed apparatus 10 for automatic loading of a shim tray 2 with shim elements in a further form of embodiment. The schematic representation is depicted in a second view, in particular a side view. The second view here represents a view rotated by 90° about the y-axis compared to the first view. The apparatus 10 of this form of embodiment includes, in addition to the components depicted and described in FIG. 1, a locking apparatus 3, a protective cover 12, a drive apparatus 11. Moreover, the components included by the loading apparatus 4 are the movement unit 42 and the fixing unit 41.

The movement unit 42 can for example include at least one robot arm. The fixing unit 41 can be moved via the movement apparatus 42 in a set movement volume, in particular inside the apparatus 10 bounded by the protective cover 12. In particular, the end effector of a robot arm can include the fixing unit 41. The control unit of the robot arm can be included by the control module 5. The movement apparatus 42 can be used to position the fixing unit 41, so that the fixing unit 41 can be placed at/on the shim element to be loaded. The movement apparatus 42 can preferably be connected to the control module 5, for example via a cable connection. The control module 5 can preferably be designed to send control signals to the movement unit 42 and/or fixing unit 41.

The fixing unit 41 can preferably include at least one element for fixing a shim element, for example a suction element and/or a magnetic element. Moreover, the fixing unit 41 can include a further movement apparatus (not shown) for moving the element to fix a shim element. For example, the fixing unit 41 can include a rotary apparatus. The fixing unit 41 is in particular designed to separate a shim element via a preferably vertical movement from the stack of the shim elements located, in particular isolated, in a cassette 6. The fixing unit 41 can in particular deposit the fixed shim element in a predetermined position and/or place in the shim tray 2. For example, it is conceivable for a shim element to be removed or inserted at a predetermined angle out of the cassette and/or into the shim tray 2. Moreover, it is conceivable for example for a shim element to be raised and/or tilted by the fixing unit 41 and then to be transported out of the cassette 6 with a movement. The fixing unit 41 and/or movement apparatus 42 can preferably also be used to remove the shim elements from the shim trays again and to deposit them into a cassette 6, if for example the trays are already loaded. This can for example enable (subsequent) corrections (of the loading of the shim tray 2).

The locking apparatus 3 can preferably be designed to accommodate at least one cassette. A locking apparatus 3 can have a locking element for each cassette 6 that can be accommodated. Each locking element can be designed so that it fits exactly in pairs to a respective cassette 6. As depicted schematically, the locking apparatus 3 can include a plate and/or a metal sheet. The plate and/or the metal sheet can in turn have locking elements, for example in the form of recesses in the plate and/or the metal sheet, edges, strips and/or predeterminedly arranged (in a pattern) fastening elements, such as bolts, pins and the like. Thanks to the locking apparatus 3 a user can preferably be enabled to position the cassettes 6 precisely. In the case of a plurality of different shim elements, it is possible to specify to a user via the locking apparatus 3 at which position which cassette should be positioned. The locking apparatus 3 can for example alternatively or additionally also include locking elements in the form of an encoding, a sensor, an electronic contact, a marking or the like.

Thanks to the protective cover 12 it can be ensured that during the loading of the shim tray 2 the apparatus 10 does not experience any significant influence by foreign particles, such as dust, and/or manual interventions, for example by a user. In other words, thanks to the protective cover 12 it can be ensured that to reduce the risk of damage the user is not able to make a manual intervention into the area of the moving axes or of the loading apparatus 4. The protective cover 12 can in particular be designed to be transparent, in order to enable a user of the apparatus 10 to observe and check the loading of the shim tray. In particular, the apparatus 10 and/or the protective cover 12 can have a sensor which can detect any opening of the protective cover 12 and/or a condition of the protective cover 12. Thereupon a signal and/or information can for example be transmitted to the control module 5 and for example the apparatus, or the loading of the shim tray 2, can be stopped.

The drive apparatus 11 can in particular enable the apparatus 10 to be displaced. Via the drive apparatus 11 the apparatus 10 is accordingly in particular designed as a mobile apparatus 10. For example, (as depicted) the drive apparatus 11 can include multiple wheels and/or a drive motor. The apparatus 10 can thus for example be pushed and/or displaced to a position by a user. The drive apparatus 11 can however also be displaced differently than depicted, for example by a crawler drive, chain drive and/or other drive.

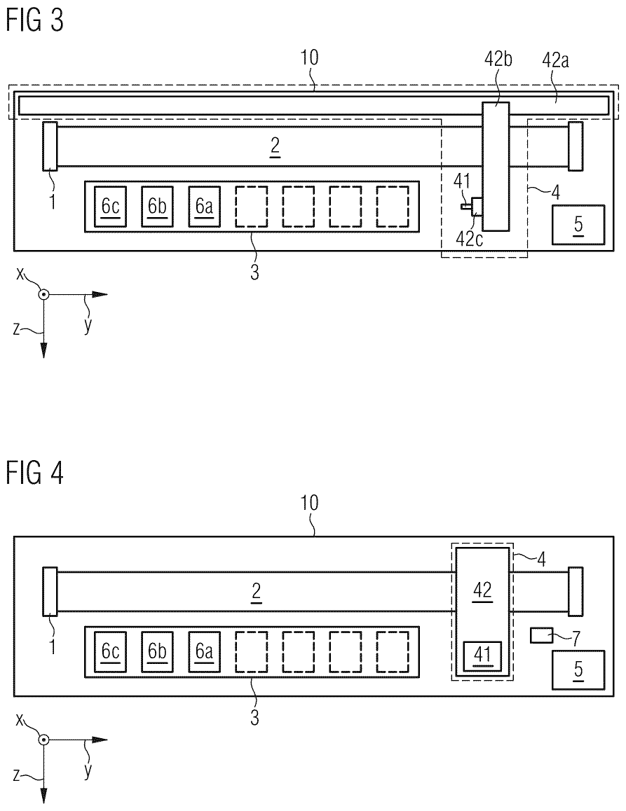

FIGS. 3, 4 and 5 show further forms of embodiment of the proposed apparatus 10 for automatic loading of a shim tray 2 with shim elements in a schematic representation. The schematic representations are depicted in a first view, in particular a plan view, corresponding to FIG. 1. In addition to the included features of FIG. 1 (and of FIG. 2) these forms of embodiment of the apparatus 10 moreover have a sensor 7, an inspection apparatus 8, an alignment apparatus 9. FIG. 3 moreover shows a loading unit 4, in particular a movement unit 42, with three linear axes 42a, 42b, 42c. The figures shown illustrate possible combinations of these features by way of example, so that further combinations not shown are also possible.

Besides the preferred loading of the shim tray 2 by a shim element from the cassette 6, further intermediate movements are conceivable, such as the rotation of the shim element, in particular via the alignment apparatus 9, and/or an examination of the shim element on an inspection apparatus 8 designed for this purpose.

The apparatus can include one or more sensors 7. The sensor 7 can for example include a level sensor, a camera, a movement sensor, a weight sensor and/or another monitoring sensor. In particular, thanks to the sensor 7 the loading apparatus, in particular the movement unit 42 and the fixing unit 41, can determine the fill level of the cassettes 6 and/or of the shim tray 2, the isolation, nature and/or orientation of the shim elements, and/or a position of a user of the apparatus 10. In particular, an inspection apparatus 8 and/or an alignment apparatus 9 can be provided, included in the sensor 7 or included in addition in the apparatus 10. The sensor 7 can preferably transmit measured signals, results and/or information to the control module 5 of the apparatus 10. On the basis of these signals and/or information the control module 5 can modify, stop, start the loading of the shim tray 2 and/or issue (warning) information to the user of the apparatus 10 via a user interface.

Via the inspection apparatus 8 the nature of a shim element and/or of a condition of a shim element can be detected. In particular, the inspection apparatus 8 can inspect, on the basis of specification information, whether the nature and/or condition of a shim element prior to loading the shim tray corresponds to a predetermined nature and/or a predetermined condition. For example, differently designed shim elements differing in dimensions, shape and/or material properties can be loaded into a shim tray, so that an inspection may be necessary before they are deposited. The inspection apparatus 8 can include sensors for detecting the nature and/or condition, such as for example a camera, a scale, a shape template and/or other detection means. The inspection apparatus 8 can be integrated into a component of the apparatus, such as for example the sensor 7 and/or the fixing unit 41. In particular, the inspection apparatus 8 can however as shown be arranged in an adjacent position in the apparatus 10 in respect of the cassettes 6. For example, after the shim elements have been removed from the cassette 6 via the loading apparatus 4 they can be transferred to the inspection apparatus 8, and deposited and inspected there. A deposit can then for example be made in the shim tray 2. It is also conceivable (other than shown) for a further loading apparatus 4 to be included in the apparatus 10 which effects the transportation of the shim elements from the cassettes 6 to the inspection unit 8.

Via the alignment apparatus 9 a spatial orientation of a shim element can be detected and/or corrected. In particular, the alignment apparatus 9 can, on the basis of orientation information, inspect whether the spatial orientation of a shim element prior to loading the shim tray corresponds to a predetermined spatial orientation. For example, the shim elements can be present in the cassettes in a different spatial orientation, so that prior to the deposit an orientation correction may be necessary. The alignment apparatus 9 can include sensors for detecting the spatial orientation, such as for example a camera, an orientation template and/or other detection means. The alignment apparatus 9 can be integrated into a component of the apparatus, such as for example the fixing unit 41. In particular, the alignment apparatus 9 can however be arranged as shown in an adjacent position in the apparatus 10 in respect of the cassettes 6. In other words, the alignment apparatus 9, as the inspection unit 8, can represent a separate workstation. For example, after the shim elements are removed from the cassette 6 via the loading apparatus 4 they can be transferred to the alignment apparatus 9, deposited there and reoriented. A deposit can then for example be made in the shim tray 2. It is also conceivable (other than shown) for a further loading apparatus 4 to be included in the apparatus 10 which effects the transportation of the shim elements from the cassettes 6 to the alignment apparatus 9.

The movement unit 42 of the loading apparatus 4, as shown in FIG. 3, preferably comprises three linear axes 42a, 42b, 42c. The linear axes 42a, 42b, 42c enable a movement of the fixing unit 41 in a first (x-direction), a second (y-direction) and a third (z-direction) direction. The linear axes 42a, 42b, 42c can be dimensioned differently according to the necessary travel paths. Each linear axis 42a, 42b, 42c can include a motor and/or drive. Depending on the travel path and/or dimension of the linear axis 42a, 42b, 42c, the linear axes 42a, 42b, 42c can be driven differently, so that for example a higher travel speed in the x-direction compared to the y-direction can be enabled. The control of the linear axes 42a, 42b, 42c can be effected in particular by the control module 5.

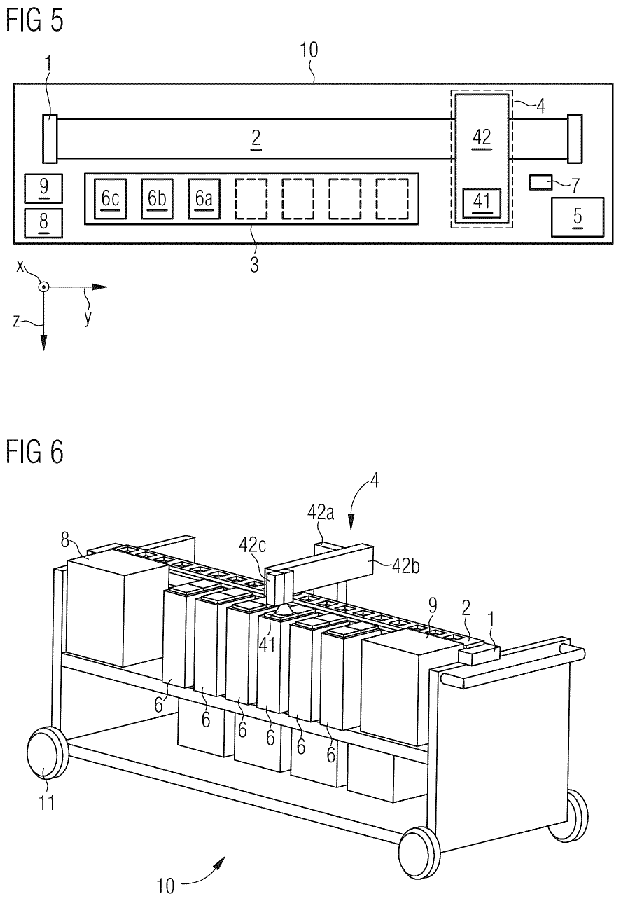

FIG. 6 shows a further form of embodiment of the proposed apparatus 10 for automatic loading of a shim tray 2 with shim elements in a schematic three-dimensional representation.

The figure illustrates a preferred combination of the proposed aspects. Also shown is a spatial view of a mobile apparatus 10 driven by the drive apparatus 11, comprising: a loading unit 4 moved by the linear axes 42a, 42b, 42c with a fixing unit 41, cassettes 6, a shim tray 2 fixed by a holding apparatus 1, an inspection apparatus 8, an alignment apparatus 9.

In conclusion, reference is once again made to the fact that the methods described in detail above and the magnetic resonance apparatus shown relate solely to exemplary embodiments that can be modified by the person skilled in the art in a variety of ways, without departing from the scope of the invention. Further, the use of the indefinite article “a” or “an” does not rule out that the features in question may also be present multiple times. Likewise the term “unit” does not rule out that the components in question consist of multiple interacting subcomponents which if appropriate may also be distributed spatially. Independent of the grammatical term usage, individuals with male, female or other gender identities are included within the term.

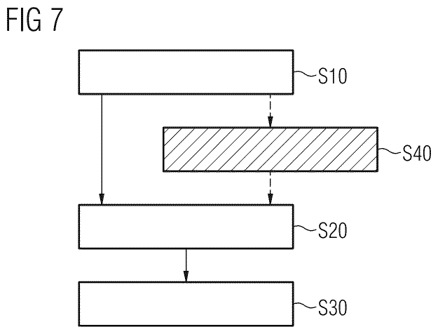

FIG. 7 shows a block diagram of a method for providing a loaded shim tray. FIG. 7 shows a form of embodiment of the method with 3 steps S10, S20, S30, as well as an optional step S40 (shown hatched).

S10 includes the detection of shim information. The detection of shim information can include multiple substeps, such as for example receipt and/or storage of the shim information by a control module. S20 includes the loading of a shim tray with shim elements via an apparatus 10 on the basis of the shim information. The loading of a shim tray with shim elements can moreover for example include the determination of control commands on the basis of the shim information. On the basis of the control commands a shim tray can be loaded automatically. In addition, further steps, such as the alignment of the orientation of a shim element and/or separating element, the inspection of the nature of a shim element and/or separating element and/or the inspection of the loading of the shim tray by a sensor can be included. S30 includes a provision of the loaded shim tray.

Moreover, the method can include the isolation (S40) of the shim elements from at least one cassette. The loading of the shim tray (S30) in this case includes the deposit of an isolated shim element on the basis of the shim information. S40 can include multiple substeps, such as for example the removal of at least one isolated shim element from the cassette. The removal of a shim element from the cassette can for example be effected via a, preferably horizontal, sideways movement. Moreover an isolated shim element can be deposited into a deposit cassette, at a deposit site and/or into another apparatus for storing isolated shim elements.

It will be understood that, although the terms first, second, etc. may be used herein to describe various elements, components, regions, layers, and/or sections, these elements, components, regions, layers, and/or sections, should not be limited by these terms. These terms are only used to distinguish one element from another. For example, a first element could be termed a second element, and, similarly, a second element could be termed a first element, without departing from the scope of example embodiments. As used herein, the term “and/or,” includes any and all combinations of one or more of the associated listed items. The phrase “at least one of” has the same meaning as “and/or”.

Spatially relative terms, such as “beneath,” “below,” “lower,” “under,” “above,” “upper,” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below,” “beneath,” or “under,” other elements or features would then be oriented “above” the other elements or features. Thus, the example terms “below” and “under” may encompass both an orientation of above and below. The device may be otherwise oriented (rotated 90 degrees or at other orientations) and the spatially relative descriptors used herein interpreted accordingly. In addition, when an element is referred to as being “between” two elements, the element may be the only element between the two elements, or one or more other intervening elements may be present.

Spatial and functional relationships between elements (for example, between modules) are described using various terms, including “on,” “connected,” “engaged,” “interfaced,” and “coupled.” Unless explicitly described as being “direct,” when a relationship between first and second elements is described in the disclosure, that relationship encompasses a direct relationship where no other intervening elements are present between the first and second elements, and also an indirect relationship where one or more intervening elements are present (either spatially or functionally) between the first and second elements. In contrast, when an element is referred to as being “directly” on, connected, engaged, interfaced, or coupled to another element, there are no intervening elements present. Other words used to describe the relationship between elements should be interpreted in a like fashion (e.g., “between,” versus “directly between,” “adjacent,” versus “directly adjacent,” etc.).

The terminology used herein is for the purpose of describing particular embodiments only and is not intended to be limiting of example embodiments. As used herein, the singular forms “a,” “an,” and “the,” are intended to include the plural forms as well, unless the context clearly indicates otherwise. As used herein, the terms “and/or” and “at least one of” include any and all combinations of one or more of the associated listed items. It will be further understood that the terms “comprises,” “comprising,” “includes,” and/or “including,” when used herein, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. Expressions such as “at least one of,” when preceding a list of elements, modify the entire list of elements and do not modify the individual elements of the list. Also, the term “example” is intended to refer to an example or illustration.

It should also be noted that in some alternative implementations, the functions/acts noted may occur out of the order noted in the figures. For example, two figures shown in succession may in fact be executed substantially concurrently or may sometimes be executed in the reverse order, depending upon the functionality/acts involved.

Unless otherwise defined, all terms (including technical and scientific terms) used herein have the same meaning as commonly understood by one of ordinary skill in the art to which example embodiments belong. It will be further understood that terms, e.g., those defined in commonly used dictionaries, should be interpreted as having a meaning that is consistent with their meaning in the context of the relevant art and will not be interpreted in an idealized or overly formal sense unless expressly so defined herein.

It is noted that some example embodiments may be described with reference to acts and symbolic representations of operations (e.g., in the form of flow charts, flow diagrams, data flow diagrams, structure diagrams, block diagrams, etc.) that may be implemented in conjunction with units and/or devices discussed above. Although discussed in a particular manner, a function or operation specified in a specific block may be performed differently from the flow specified in a flowchart, flow diagram, etc. For example, functions or operations illustrated as being performed serially in two consecutive blocks may actually be performed simultaneously, or in some cases be performed in reverse order. Although the flowcharts describe the operations as sequential processes, many of the operations may be performed in parallel, concurrently or simultaneously. In addition, the order of operations may be re-arranged. The processes may be terminated when their operations are completed, but may also have additional steps not included in the figure. The processes may correspond to methods, functions, procedures, subroutines, subprograms, etc.

Specific structural and functional details disclosed herein are merely representative for purposes of describing example embodiments. The present invention may, however, be embodied in many alternate forms and should not be construed as limited to only the embodiments set forth herein.

In addition, or alternative, to that discussed above, units and/or devices according to one or more example embodiments may be implemented using hardware, software, and/or a combination thereof. For example, hardware devices may be implemented using processing circuitry such as, but not limited to, a processor, Central Processing Unit (CPU), a Graphics Processing Unit (GPU), a controller, an arithmetic logic unit (ALU), a digital signal processor, a microcomputer, a field programmable gate array (FPGA), a System-on-Chip (SoC), a programmable logic unit, a microprocessor, or any other device capable of responding to and executing instructions in a defined manner. Portions of the example embodiments and corresponding detailed description may be presented in terms of software, or algorithms and symbolic representations of operation on data bits within a computer memory. These descriptions and representations are the ones by which those of ordinary skill in the art effectively convey the substance of their work to others of ordinary skill in the art. An algorithm, as the term is used here, and as it is used generally, is conceived to be a self-consistent sequence of steps leading to a desired result. The steps are those requiring physical manipulations of physical quantities. Usually, though not necessarily, these quantities take the form of optical, electrical, or magnetic signals capable of being stored, transferred, combined, compared, and otherwise manipulated. It has proven convenient at times, principally for reasons of common usage, to refer to these signals as bits, values, elements, symbols, characters, terms, numbers, or the like.

It should be borne in mind that all of these and similar terms are to be associated with the appropriate physical quantities and are merely convenient labels applied to these quantities. Unless specifically stated otherwise, or as is apparent from the discussion, terms such as “processing” or “computing” or “calculating” or “determining” of “displaying” or the like, refer to the action and processes of a computer system, or similar electronic computing device/hardware, that manipulates and transforms data represented as physical, electronic quantities within the computer system's registers and memories into other data similarly represented as physical quantities within the computer system memories or registers or other such information storage, transmission or display devices.

In this application, including the definitions below, the term ‘module’ or the term ‘controller’ may be replaced with the term ‘circuit.’ The term ‘module’ may refer to, be part of, or include processor hardware (shared, dedicated, or group) that executes code and memory hardware (shared, dedicated, or group) that stores code executed by the processor hardware.

The module may include one or more interface circuits. In some examples, the interface circuits may include wired or wireless interfaces that are connected to a local area network (LAN), the Internet, a wide area network (WAN), or combinations thereof. The functionality of any given module of the present disclosure may be distributed among multiple modules that are connected via interface circuits. For example, multiple modules may allow load balancing. In a further example, a server (also known as remote, or cloud) module may accomplish some functionality on behalf of a client module.

Software may include a computer program, program code, instructions, or some combination thereof, for independently or collectively instructing or configuring a hardware device to operate as desired. The computer program and/or program code may include program or computer-readable instructions, software components, software modules, data files, data structures, and/or the like, capable of being implemented by one or more hardware devices, such as one or more of the hardware devices mentioned above. Examples of program code include both machine code produced by a compiler and higher level program code that is executed using an interpreter.

For example, when a hardware device is a computer processing device (e.g., a processor, Central Processing Unit (CPU), a controller, an arithmetic logic unit (ALU), a digital signal processor, a microcomputer, a microprocessor, etc.), the computer processing device may be configured to carry out program code by performing arithmetical, logical, and input/output operations, according to the program code. Once the program code is loaded into a computer processing device, the computer processing device may be programmed to perform the program code, thereby transforming the computer processing device into a special purpose computer processing device. In a more specific example, when the program code is loaded into a processor, the processor becomes programmed to perform the program code and operations corresponding thereto, thereby transforming the processor into a special purpose processor.

Software and/or data may be embodied permanently or temporarily in any type of machine, component, physical or virtual equipment, or computer storage medium or device, capable of providing instructions or data to, or being interpreted by, a hardware device. The software also may be distributed over network coupled computer systems so that the software is stored and executed in a distributed fashion. In particular, for example, software and data may be stored by one or more computer readable recording mediums, including the tangible or non-transitory computer-readable storage media discussed herein.

Even further, any of the disclosed methods may be embodied in the form of a program or software. The program or software may be stored on a non-transitory computer readable medium and is adapted to perform any one of the aforementioned methods when run on a computer device (a device including a processor). Thus, the non-transitory, tangible computer readable medium, is adapted to store information and is adapted to interact with a data processing facility or computer device to execute the program of any of the above mentioned embodiments and/or to perform the method of any of the above mentioned embodiments.

Example embodiments may be described with reference to acts and symbolic representations of operations (e.g., in the form of flow charts, flow diagrams, data flow diagrams, structure diagrams, block diagrams, etc.) that may be implemented in conjunction with units and/or devices discussed in more detail below. Although discussed in a particular manner, a function or operation specified in a specific block may be performed differently from the flow specified in a flowchart, flow diagram, etc. For example, functions or operations illustrated as being performed serially in two consecutive blocks may actually be performed simultaneously, or in some cases be performed in reverse order.

According to one or more example embodiments, computer processing devices may be described as including various functional units that perform various operations and/or functions to increase the clarity of the description. However, computer processing devices are not intended to be limited to these functional units. For example, in one or more example embodiments, the various operations and/or functions of the functional units may be performed by other ones of the functional units. Further, the computer processing devices may perform the operations and/or functions of the various functional units without sub-dividing the operations and/or functions of the computer processing units into these various functional units.

Units and/or devices according to one or more example embodiments may also include one or more storage devices. The one or more storage devices may be tangible or non-transitory computer-readable storage media, such as random access memory (RAM), read only memory (ROM), a permanent mass storage device (such as a disk drive), solid state (e.g., NAND flash) device, and/or any other like data storage mechanism capable of storing and recording data. The one or more storage devices may be configured to store computer programs, program code, instructions, or some combination thereof, for one or more operating systems and/or for implementing the example embodiments described herein. The computer programs, program code, instructions, or some combination thereof, may also be loaded from a separate computer readable storage medium into the one or more storage devices and/or one or more computer processing devices using a drive mechanism. Such separate computer readable storage medium may include a Universal Serial Bus (USB) flash drive, a memory stick, a Blu-ray/DVD/CD-ROM drive, a memory card, and/or other like computer readable storage media. The computer programs, program code, instructions, or some combination thereof, may be loaded into the one or more storage devices and/or the one or more computer processing devices from a remote data storage device via a network interface, rather than via a local computer readable storage medium. Additionally, the computer programs, program code, instructions, or some combination thereof, may be loaded into the one or more storage devices and/or the one or more processors from a remote computing system that is configured to transfer and/or distribute the computer programs, program code, instructions, or some combination thereof, over a network. The remote computing system may transfer and/or distribute the computer programs, program code, instructions, or some combination thereof, via a wired interface, an air interface, and/or any other like medium.

The one or more hardware devices, the one or more storage devices, and/or the computer programs, program code, instructions, or some combination thereof, may be specially designed and constructed for the purposes of the example embodiments, or they may be known devices that are altered and/or modified for the purposes of example embodiments.

A hardware device, such as a computer processing device, may run an operating system (OS) and one or more software applications that run on the OS. The computer processing device also may access, store, manipulate, process, and create data in response to execution of the software. For simplicity, one or more example embodiments may be exemplified as a computer processing device or processor; however, one skilled in the art will appreciate that a hardware device may include multiple processing elements or processors and multiple types of processing elements or processors. For example, a hardware device may include multiple processors or a processor and a controller. In addition, other processing configurations are possible, such as parallel processors.

The computer programs include processor-executable instructions that are stored on at least one non-transitory computer-readable medium (memory). The computer programs may also include or rely on stored data. The computer programs may encompass a basic input/output system (BIOS) that interacts with hardware of the special purpose computer, device drivers that interact with particular devices of the special purpose computer, one or more operating systems, user applications, background services, background applications, etc. As such, the one or more processors may be configured to execute the processor executable instructions.

The computer programs may include: (i) descriptive text to be parsed, such as HTML (hypertext markup language) or XML (extensible markup language), (ii) assembly code, (iii) object code generated from source code by a compiler, (iv) source code for execution by an interpreter, (v) source code for compilation and execution by a just-in-time compiler, etc. As examples only, source code may be written using syntax from languages including C, C++, C#, Objective-C, Haskell, Go, SQL, R, Lisp, Java®, Fortran, Perl, Pascal, Curl, OCaml, Javascript®, HTML5, Ada, ASP (active server pages), PHP, Scala, Eiffel, Smalltalk, Erlang, Ruby, Flash®, Visual Basic®, Lua, and Python®.

Further, at least one example embodiment relates to the non-transitory computer-readable storage medium including electronically readable control information (processor executable instructions) stored thereon, configured in such that when the storage medium is used in a controller of a device, at least one embodiment of the method may be carried out.

The computer readable medium or storage medium may be a built-in medium installed inside a computer device main body or a removable medium arranged so that it can be separated from the computer device main body. The term computer-readable medium, as used herein, does not encompass transitory electrical or electromagnetic signals propagating through a medium (such as on a carrier wave); the term computer-readable medium is therefore considered tangible and non-transitory. Non-limiting examples of the non-transitory computer-readable medium include, but are not limited to, rewriteable non-volatile memory devices (including, for example flash memory devices, erasable programmable read-only memory devices, or a mask read-only memory devices); volatile memory devices (including, for example static random access memory devices or a dynamic random access memory devices); magnetic storage media (including, for example an analog or digital magnetic tape or a hard disk drive); and optical storage media (including, for example a CD, a DVD, or a Blu-ray Disc). Examples of the media with a built-in rewriteable non-volatile memory, include but are not limited to memory cards; and media with a built-in ROM, including but not limited to ROM cassettes; etc. Furthermore, various information regarding stored images, for example, property information, may be stored in any other form, or it may be provided in other ways.

The term code, as used above, may include software, firmware, and/or microcode, and may refer to programs, routines, functions, classes, data structures, and/or objects. Shared processor hardware encompasses a single microprocessor that executes some or all code from multiple modules. Group processor hardware encompasses a microprocessor that, in combination with additional microprocessors, executes some or all code from one or more modules. References to multiple microprocessors encompass multiple microprocessors on discrete dies, multiple microprocessors on a single die, multiple cores of a single microprocessor, multiple threads of a single microprocessor, or a combination of the above.

Shared memory hardware encompasses a single memory device that stores some or all code from multiple modules. Group memory hardware encompasses a memory device that, in combination with other memory devices, stores some or all code from one or more modules.

The term memory hardware is a subset of the term computer-readable medium. The term computer-readable medium, as used herein, does not encompass transitory electrical or electromagnetic signals propagating through a medium (such as on a carrier wave); the term computer-readable medium is therefore considered tangible and non-transitory. Non-limiting examples of the non-transitory computer-readable medium include, but are not limited to, rewriteable non-volatile memory devices (including, for example flash memory devices, erasable programmable read-only memory devices, or a mask read-only memory devices); volatile memory devices (including, for example static random access memory devices or a dynamic random access memory devices); magnetic storage media (including, for example an analog or digital magnetic tape or a hard disk drive); and optical storage media (including, for example a CD, a DVD, or a Blu-ray Disc). Examples of the media with a built-in rewriteable non-volatile memory, include but are not limited to memory cards; and media with a built-in ROM, including but not limited to ROM cassettes; etc. Furthermore, various information regarding stored images, for example, property information, may be stored in any other form, or it may be provided in other ways.

The apparatuses and methods described in this application may be partially or fully implemented by a special purpose computer created by configuring a general purpose computer to execute one or more particular functions embodied in computer programs. The functional blocks and flowchart elements described above serve as software specifications, which can be translated into the computer programs by the routine work of a skilled technician or programmer.

Although described with reference to specific examples and drawings, modifications, additions and substitutions of example embodiments may be variously made according to the description by those of ordinary skill in the art. For example, the described techniques may be performed in an order different with that of the methods described, and/or components such as the described system, architecture, devices, circuit, and the like, may be connected or combined to be different from the above-described methods, or results may be appropriately achieved by other components or equivalents.

1. An apparatus for automatic loading of a shim tray with shim elements, comprising:
a holding apparatus to a shim tray;
at least one cassette, the cassette configured to stock at least one of shim elements or separating elements;
a loading apparatus, the loading apparatus configured to deposit at least a portion of the at least one of the shim elements or separating elements from the at least one cassette into a shim tray positioned by the holding apparatus;
a controller configured to control the loading apparatus.

2. The apparatus of claim 1, wherein
the loading apparatus includes a movement unit and a fixing unit, and
the movement unit is configured to at least one of move or position the fixing unit and the fixing unit is configured to fix at least one of at least one shim element or at least one separating element.

3. The apparatus of claim 2, wherein
the movement unit includes at least one of up to three linear movement elements or up to three rotary elements,
the linear movement elements are configured for a linear movement of the fixing unit in a first direction, a second direction and a third direction, and
the rotary elements are configured for at least one of an orientation or a rotation of the fixing unit about a first axis of rotation, a second axis of rotation and a third axis of rotation.

4. The apparatus of claim 2, wherein
the fixing unit includes a suction element, and
the suction element is configured to fix the at least one of the at least one shim element or the at least one separating element by generating a negative pressure.

5. The apparatus of claim 2, wherein
the fixing unit includes a magnetic element, and
the magnetic element is configured to fix the at least one of the at least one shim element or the at least one separating element magnetically.

6. The apparatus of claim 1, further comprising:
at least one sensor configured to monitor the automatic loading of the shim tray.

7. The apparatus of claim 1, wherein the apparatus is a mobile apparatus.

8. The apparatus of claim 1, further comprising:
a locking apparatus, wherein the locking apparatus is designed to lock at least one cassette.

9. The apparatus of claim 8, wherein
the locking apparatus configured to accommodate the at least one cassette, the locking apparatus includes a locking element for each cassette to be accommodated, and
each locking element is configured to lock the at least one cassette in pairs.

10. The apparatus of claim 1, further comprising:
at least one isolation apparatus for the at least one cassette, and
the at least one isolation apparatus is configured to output at least one of an isolated shim element or an isolated separating element from the at least one cassette.

11. The apparatus of claim 1, further comprising:
an inspection apparatus, the inspection apparatus configured to detect at least one of a nature or a condition of at least one of at least one shim element or at least one separating element prior to loading the shim tray and to inspect the at least one of the at least one shim element or the at least one separating element based on specification information.

12. The apparatus of claim 1, further comprising:
an alignment apparatus, the alignment apparatus configured to align at least one of at least one shim element or at least one separating element prior to loading the shim tray based on orientation information.

13. The apparatus of claim 1, wherein the controller is configured to control the loading apparatus based on shim information of a magnetic resonance apparatus.

14. A method for providing a loaded shim tray, comprising:
detecting shim information;
loading a shim tray with shim elements via the apparatus of claim 1 based on the shim information; and
providing the loaded shim tray.

15. The method of claim 14, further comprising:
isolating the shim elements from the at least one cassette, wherein the loading the shim tray includes depositing an isolated shim element based on the shim information.

16. The apparatus of claim 3, wherein
the fixing unit includes a magnetic element, and
the magnetic element is configured to fix the at least one of the at least one shim element or the at least one separating element magnetically.

17. The apparatus of claim 2, further comprising:
at least one isolation apparatus for the at least one cassette, and
the at least one isolation apparatus is configured to output at least one of an isolated shim element or an isolated separating element from the at least one cassette.

18. The apparatus of claim 17, further comprising:
an inspection apparatus, the inspection apparatus configured to detect at least one of a nature or a condition of at least one of at least one shim element or at least one separating element prior to loading the shim tray and to inspect the at least one of the at least one shim element or the at least one separating element based on specification information.

19. The apparatus of claim 18, further comprising:
an alignment apparatus, the alignment apparatus configured to align at least one of at least one shim element or at least one separating element prior to loading the shim tray based on orientation information.

20. The apparatus of claim 19, wherein the controller is configured to control the loading apparatus based on shim information of a magnetic resonance apparatus.
